(19) United States
(12) Patent Application Publication
(10) Pub. No.: US 2024/0237347 A1
(43) Pub. Date: Jul. 11, 2024

(54) METHOD OF FABRICATING SEMICONDUCTOR DEVICE

(71) Applicant: SAMSUNG ELECTRONICS CO., LTD., Suwon-si (KR)

(72) Inventors: Yongmin KIM, Suwon-si (KR); Seongsoo MOON, Suwon-si (KR); SEUNGHAK PARK, Suwon-si (KR); Junseok PARK, Suwon-si (KR); KI-BONG SEO, Suwon-si (KR); Howon SEO, Suwon-si (KR); Mingyoo CHOI, Suwon-si (KR)

(21) Appl. No.: 18/380,422

(22) Filed: Oct. 16, 2023

(30) Foreign Application Priority Data
Jan. 6, 2023 (KR) 10-2023-0002383

(51) Int. Cl. H10B 43/27; H10B 43/10; H10B 43/35; H10B 43/40

(52) U.S. Cl. CPC H10B 43/27; H10B 43/10; H10B 43/35; H10B 43/40

(57) ABSTRACT

A method of fabricating a semiconductor device including: alternately stacking first interlayer insulating layers and first sacrificial layers on a substrate to form a first mold structure; forming a dummy hole penetrating the first mold structure; forming a dummy sacrificial pillar in the dummy hole, wherein the formation of the dummy sacrificial pillar includes forming a first recessed key region to expose a portion of an inner side surface of the dummy hole; and forming a second mold structure with a substantially uniform thickness on the first recessed key region and the first mold structure, wherein a top surface of the second mold structure has a second recessed key region corresponding to the first recessed key region.

### CROSS-REFERENCE TO RELATED APPLICATION

This U.S. non-provisional patent application claims priority under 35 U.S.C. § 119 to Korean Patent Application No. 10-2023-0002383, filed on Jan. 6, 2023, in the Korean Intellectual Property Office, the disclosure of which is incorporated by reference herein in its entirety.

### TECHNICAL FIELD

The present inventive concept relates to a method of fabricating a semiconductor device.

### DISCUSSION OF THE RELATED ART

A semiconductor device capable of storing a large capacity of data is desired as a part of an electronic system. Accordingly, many studies are being conducted to increase the data storage capacity of the semiconductor device. For example, semiconductor devices, in which memory cells are three-dimensionally arranged, are currently under development.

### SUMMARY

According to an embodiment of the present inventive concept, a method of fabricating a semiconductor device including: alternately stacking first interlayer insulating layers and first sacrificial layers on a substrate to form a first mold structure; forming a dummy hole penetrating the first mold structure; forming a dummy sacrificial pillar in the dummy hole, wherein the formation of the dummy sacrificial pillar includes forming a first recessed key region to expose a portion of an inner side surface of the dummy hole; and forming a second mold structure with a substantially uniform thickness on the first recessed key region and the first mold structure, wherein a top surface of the second mold structure has a second recessed key region corresponding to the first recessed key region.

According to an embodiment of the present inventive concept, a method of fabricating a semiconductor device including: providing a substrate including a first region and a second region; alternately stacking first interlayer insulating layers and first sacrificial layers on the substrate to form a first mold structure; forming lower channel holes and dummy holes penetrating the first mold structure, wherein the lower channel holes and the dummy holes are provided on the first region and the second region, respectively; sequentially forming first and second sacrificial pillars in each of the lower channel holes; sequentially forming first and second dummy sacrificial pillars in each of the dummy holes; removing the second dummy sacrificial pillar from the second region to form a first recessed key region exposing a portion of an inner side surface of each of the dummy holes; alternately stacking second interlayer insulating layers and second sacrificial layers on the first mold structure to form a second mold structure, wherein a top surface of the second mold structure in the second region has a second recessed key region overlapping to the first recessed key region; and forming upper channel holes on the first region and penetrating the second mold structure, wherein the upper channel holes expose the second sacrificial pillars in the lower channel holes, respectively, wherein the forming of the upper channel holes includes patterning the second mold structure using the second recessed key region as an alignment key.

### BRIEF DESCRIPTION OF THE DRAWINGS

The above and other features of the present inventive concept will become more apparent by describing in detail exemplary embodiments thereof, with reference to the accompanying drawings, in which:

FIG. 1 is a diagram illustrating a substrate, on which semiconductor devices according to an embodiment of the present inventive concept are integrated.

FIG. 2 is a plan view illustrating a semiconductor device according to an embodiment of the present inventive concept.

FIGS. 3, 4, 5, 6, 7, 8, 9, 10, 11, 12, 13, and 14 are sectional views, which are taken along lines A-A′ and B-B′ of FIG. 2 to illustrate a method of fabricating a semiconductor device according to an embodiment of the present inventive concept.

FIG. 15 is a sectional view illustrating a semiconductor device according to an embodiment of the present inventive concept.

FIG. 16 is a diagram schematically illustrating an electronic system, which includes a semiconductor device according to an embodiment of the present inventive concept.

FIG. 17 is a perspective view schematically illustrating an electronic system, which includes a semiconductor device according to an embodiment of the present inventive concept.

FIGS. 18 and 19 are sectional views illustrating semiconductor packages according to some embodiments of the present inventive concept.

### DETAILED DESCRIPTION OF THE EMBODIMENTS

Embodiments of the present inventive concept will now be described more fully with reference to the accompanying drawings, in which example embodiments are shown.

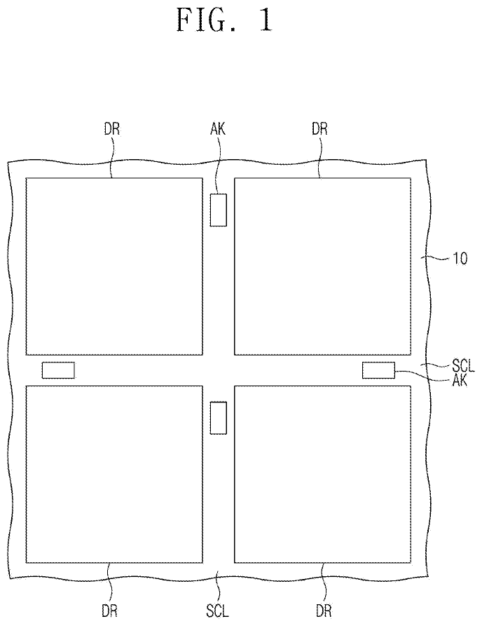

FIG. 1 is a diagram illustrating a semiconductor substrate, on which semiconductor devices according to an embodiment of the present inventive concept are integrated.

Referring to FIG. 1, a semiconductor substrate 10 (e.g., a wafer) may include chip regions DR, on which semiconductor chips are respectively formed, and a scribe line region SCL provided between the chip regions DR. The chip regions DR may be two-dimensionally arranged in first and second directions D1 and D2 crossing each other. Each of the chip regions DR may be enclosed by the scribe line region SCL. For example, the scribe line region SCL may be disposed between the chip regions DR, which are adjacent to each other in the first direction D1, and between the chip regions DR, which are adjacent to each other in the second direction D2.

The semiconductor substrate 10 may be, for example, a bulk silicon wafer, a silicon-on-insulator (SOI) wafer, a germanium wafer, a germanium-on-insulator (GOI) wafer, a silicon-germanium wafer, or a substrate including an epitaxial layer formed by a selective epitaxial growth (SEG) process.

In an embodiment of the present inventive concept, a semiconductor device may be formed to include memory cells, which are three-dimensionally arranged on each of the chip regions DR of the semiconductor substrate 10.

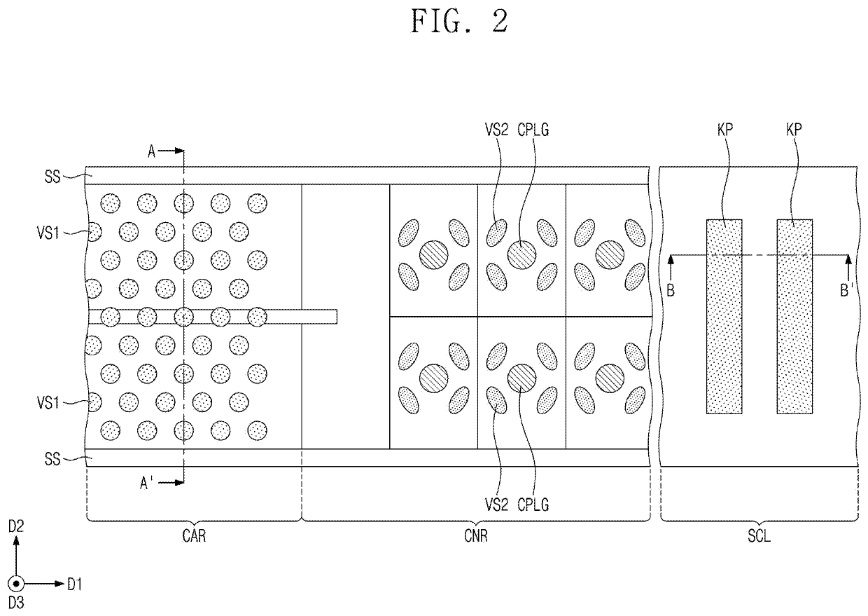

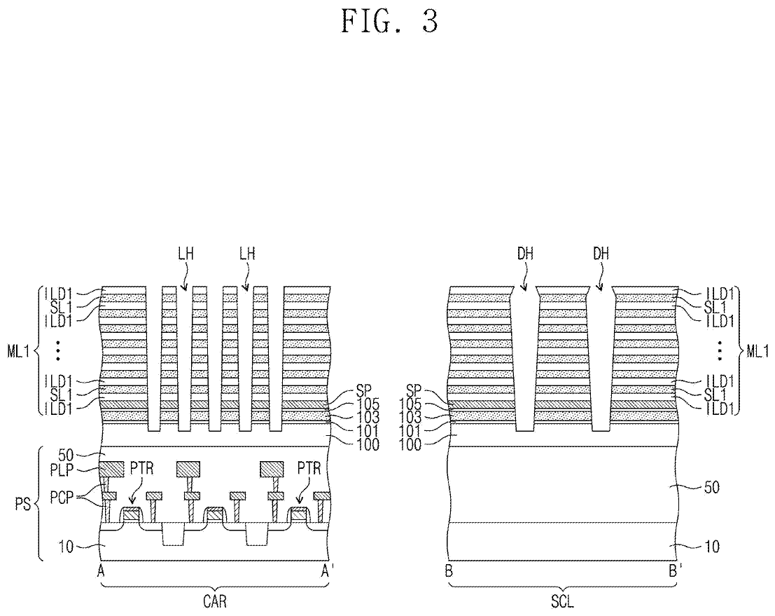

FIG. 2 is a plan view illustrating a semiconductor device according to an embodiment of the present inventive concept. FIGS. 3 to 14 are sectional views, which are taken along lines A-A′ and B-B′ of FIG. 2 to illustrate a method of fabricating a semiconductor device according to an embodiment of the present inventive concept.

Referring to FIGS. 2 and 3, a peripheral circuit structure PS may be formed on the semiconductor substrate 10.

The semiconductor substrate 10 may include the chip regions DR (e.g., of FIG. 1) and the scribe line region SCL, as previously described with reference to FIG. 1. In the semiconductor substrate 10, each of the chip regions DR (e.g., of FIG. 1) may include a cell array region CAR and a connection region CNR adjacent to the cell array region CAR. The semiconductor substrate 10 may be a silicon wafer.

The formation of the peripheral circuit structure PS may include forming peripheral circuits PTR on the semiconductor substrate 10, forming peripheral interconnection structures PCP and PLP that are connected to the peripheral circuits PTR, and forming a peripheral circuit insulating layer 50.

Row and column decoders, page buffers, and control circuits, which are used as the peripheral circuits PTR, may be formed on the semiconductor substrate 10. Here, the peripheral circuits PTR may include, for example, MOS transistors, and in this case, the semiconductor substrate 10 may be used as channel regions of the MOS transistors.

The peripheral circuit insulating layer 50 may include one insulating layer or a plurality of vertically-stacked insulating layers covering the peripheral circuits PTR. In an embodiment of the present inventive concept, the peripheral circuit insulating layer 50 may include a silicon oxide layer, a silicon nitride layer, a silicon oxynitride layer, and/or a low-k dielectric layer.

The formation of the peripheral interconnection structures may include forming the peripheral contact plugs PCP to penetrate portions of the peripheral circuit insulating layer 50 and forming the peripheral circuit lines PLP that are connected to the peripheral contact plugs PCP.

Next, a semiconductor layer 100 may be formed on the peripheral circuit insulating layer 50. The semiconductor layer 100 may be formed by depositing a semiconductor material. The semiconductor layer 100 may be formed of or include at least one of, for example, silicon (Si), germanium (Ge), silicon germanium (SiGe), gallium arsenic (GaAs), indium gallium arsenic (InGaAs), and/or aluminum gallium arsenic (AlGaAs). The semiconductor layer 100 may be formed of or include a doped semiconductor material and/or an undoped or intrinsic semiconductor material. The semiconductor layer 100 may have one of, for example, polycrystalline, amorphous, and single-crystalline structures. The semiconductor layer 100 may be formed of or include at least one of, for example, metallic materials (e.g., tungsten), conductive metal nitride materials, conductive metal silicide materials, conductive metal oxide materials, or combinations thereof.

In an embodiment of the present inventive concept, a first insulating layer 101, a second insulating layer 103, and a third insulating layer 105 may be sequentially stacked on the semiconductor layer 100. For example, the first insulating layer 101 may be formed by thermally oxidizing a surface of the semiconductor layer 100 or by depositing a silicon oxide layer. For example, the second insulating layer 103 may be formed of a material having an etch selectivity with respect to the first insulating layer 101 and the third insulating layer 105. As an example, the second insulating layer 103 may be at least one of a silicon nitride layer, a silicon oxynitride layer, a silicon carbide layer, and/or a silicon germanium layer. The third insulating layer 105 may be formed by depositing a silicon oxide layer.

A support conductive layer SP may be deposited on the third insulating layer 105 and may have a substantially uniform thickness. In an example embodiment of the present inventive concept, in the cell array region CAR, the support conductive layer SP may penetrate portions of the first insulating layer 101, the second insulating layer 103, and the third insulating layer 105 and may be disposed on the semiconductor layer 100. For example, the support conductive layer SP may be in direct contact with the semiconductor layer 100. For example, the support conductive layer SP may be a poly-silicon layer, which is doped with n-type dopants and/or carbon (C).

In addition, in an embodiment of the present inventive concept, the formation of the first, second, and third insulating layers 101, 103, and 105 and the support conductive layer SP may be omitted.

A first mold structure ML1 may be formed on the support conductive layer SP. The formation of the first mold structure ML1 may include first interlayer insulating layers ILD1 and first sacrificial layers SL1 alternately stacked on each other.

The first sacrificial layers SL1 of the first mold structure ML1 may be formed of a material which can be etched with a high etch selectivity with respect to the first interlayer insulating layers ILD1. As an example, the first sacrificial layers SL1 may be formed of or include an insulating material different from that of the first interlayer insulating layers LD1. For example, the first sacrificial layers SL1 may be formed of the same material as the second insulating layer 103. For example, the first sacrificial layers SL1 may be formed of or include silicon nitride, and the first interlayer insulating layers ILD1 may be formed of or include at least one of silicon oxide, silicon oxynitride, and/or low-k dielectric materials.

For example, the first interlayer insulating layers ILD1 and the first sacrificial layers SL1 may be deposited by a thermal chemical vapor deposition (Thermal CVD) process, a plasma-enhanced chemical vapor deposition (PE-CVD) process, a physical chemical vapor deposition (physical CVD) process, or an atomic layer deposition (ALD) process. The first interlayer insulating layers ILD1 and the first sacrificial layers SL1 may be deposited in an in-situ manner.

Next, referring to FIGS. 2 and 3, lower channel holes LH may be formed in the cell array region CAR to penetrate the first mold structure ML1, and dummy holes DH may be formed in the scribe line region SCL to penetrate the first mold structure ML1.

For example, the formation of the lower channel holes LH and the dummy holes DH may include forming a mask pattern, which has openings defining positions of the lower channel holes LH, on the first mold structure ML1, and anisotropically etching the first mold structure ML1, the support conductive layer SP, and the first, second, and third insulating layers 101, 103, and 105 using the mask pattern as an etch mask. Here, the formation of the mask pattern may include a lithography process that is performed using extreme ultraviolet (EUV) light. The anisotropic etching process on the first mold structure ML1 may be performed using an etch recipe that can continuously and anisotropically etch the first sacrificial layers SL1 and the first interlayer insulating layers ILD1. For example, the anisotropic etching process may include a plasma etching process, a reactive ion etching (RIE) process, an inductively-coupled-plasma reactive-ion-etching (ICP-RIE) process, or an ion beam etching (IBE) process.

The lower channel holes LH and the dummy holes DH may penetrate the support conductive layer SP and the first, second, and third insulating layers 101, 103, and 105 and may expose the semiconductor layer 100. When viewed in a plan view, the lower channel holes LH may be arranged in a specific direction or in a zigzag shape. For example, the lower channel holes LH may be alternately arranged. Each of the dummy holes DH may be a bar- or trench-shaped region having a long axis parallel to the first or second direction D1 or D2. In addition, the dummy holes DH may have a circular, elliptical, polygonal, or cross shape. A width of each dummy hole DH may be larger than a width of the lower channel hole LH. A height of the lower channel holes LH and the dummy holes DH may be about 30, 40, or 50 times greater than or more than the width of the lower channel holes LH.

A bowing phenomenon may occur during the anisotropic etching process of forming the dummy holes DH, and thus, each of the dummy holes DH may include an upper region, a lower region, and a bowing region, which is formed between the upper and lower regions and has the largest width when compared to the widths of the lower region and the upper region. In each of the dummy holes DH, an upper region may have a negatively sloped side surface, and a lower region may have a positively sloped side surface.

In an embodiment of the present inventive concept, the dummy holes DH may be formed by an additional etching process, which is different from the anisotropic etching process that is performed to form the lower channel holes LH. Furthermore, in some embodiments of the present inventive concept, the dummy holes DH may be formed by anisotropically etching a thick insulating layer, not the first mold structure ML1.

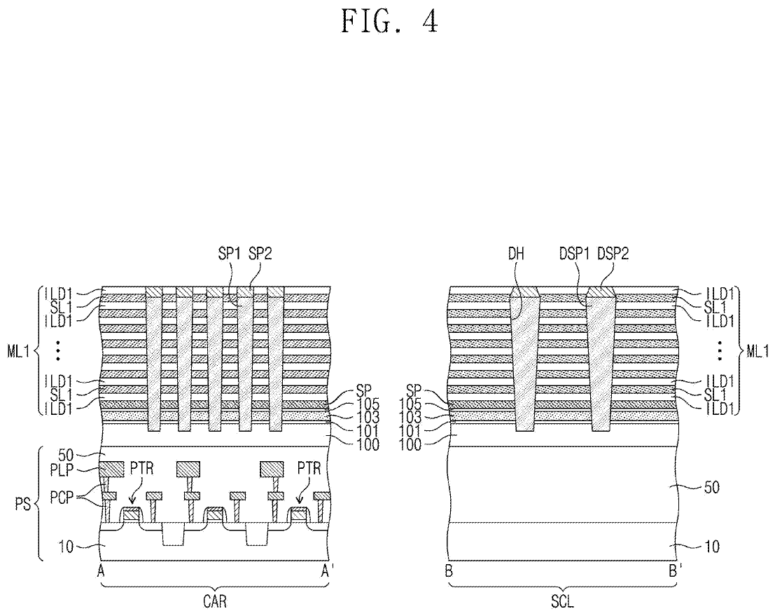

Referring to FIG. 4, first and second sacrificial pillars SP1 and SP2 may be formed in each of the lower channel holes LH, and first and second dummy sacrificial pillars DSP1 and DSP2 may be formed in each of the dummy holes DH.

For example, the formation of the first sacrificial pillars SP1 may include forming a first vertical sacrificial layer to fill the lower channel holes LH and performing an isotropic etching process on a portion of the first vertical sacrificial layer to partially expose inner surfaces of the lower channel holes LH. Here, the first sacrificial pillars SP1 may be formed of or include a material having an etch selectivity with respect to the first mold structure ML1. In an embodiment of the present inventive concept, the first sacrificial pillars SP1 may be formed of or include at least one of polysilicon, carbon-containing materials, or metallic materials (e.g., W and TiN). In an embodiment of the present inventive concept, the first sacrificial pillars SP1 may be formed of or include a first metal material (e.g., tungsten (W)).

Next, the formation of the second sacrificial pillars SP2 may include forming a second vertical sacrificial layer to fill remaining space of the lower channel holes LH that is filled with the first sacrificial pillars SP1 and performing a planarization process on the second vertical sacrificial layer to expose an inner surface of the uppermost one of the first interlayer insulating layers ILD1. Here, the second vertical sacrificial layer may be formed of or include a material having an etch selectivity with respect to the first mold structure ML1 and the first sacrificial pillars SP1. As an example, the second sacrificial pillars SP2 may be formed of or include at least one of polysilicon, carbon-containing materials, or metallic materials (e.g., W and TiN). In an embodiment of the present inventive concept, the second sacrificial pillars SP2 may be formed of or include a second metal material (e.g., titanium nitride (TiN)) having an etch selectivity with respect to the first sacrificial pillars SP1.

In an embodiment of the present inventive concept, the first dummy sacrificial pillars DSP1 may be formed in the dummy holes DH, during the formation of the first sacrificial pillars SP1 in the cell array region CAR, and the second dummy sacrificial pillars DSP2 may be formed during the formation of the second sacrificial pillars SP2. The first dummy sacrificial pillars DSP1 may be formed of the same material as the first sacrificial pillars SP1, and the second dummy sacrificial pillars DSP2 may be formed of the same material as the second sacrificial pillars SP2.

The first sacrificial pillars SP1 and the first dummy sacrificial pillars DSP1 may have top surfaces that are located at a level lower than a top surface of the first mold structure ML1. A depth (or height) of a first recessed key region, which will be formed in a subsequent step, may depend on a difference in height between the top surfaces of the first sacrificial pillars SP1 and the first mold structure ML1 and between the top surfaces of the first dummy sacrificial pillars DSP1 and the first mold structure ML1.

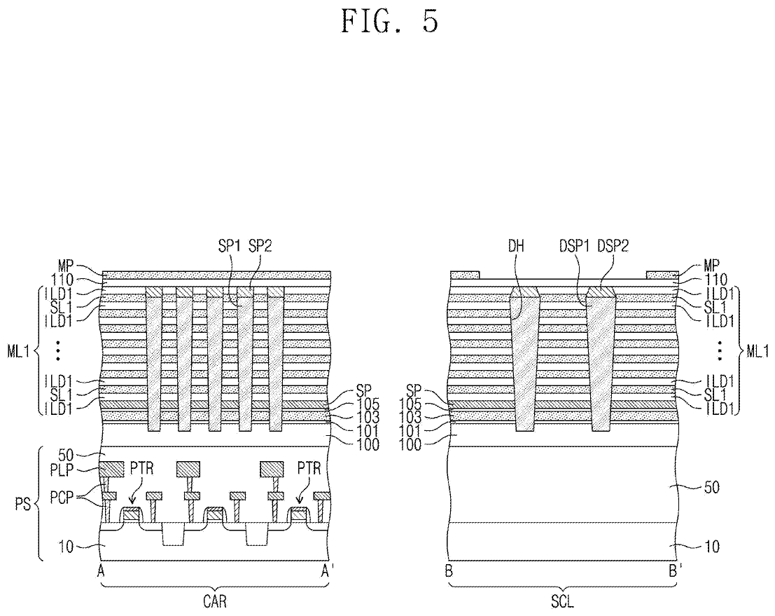

Referring to FIG. 5, a buffer layer 110 may be formed on the first mold structure ML1. The buffer layer 110 may be formed of or include, for example, silicon oxide or silicon oxynitride. In addition, the buffer layer 110 may be formed of or include the same material as the second dummy sacrificial pillars DSP2.

A mask pattern MP may be formed on the buffer layer 110. In an embodiment of the present inventive concept, the mask pattern MP may be formed of or include a photoresist material.

A mask pattern MP1 may have an opening, which is formed on the scribe line region SCL and is overlapped with the dummy holes DH. The opening of the mask pattern MP1 may be formed by coating a photoresist layer on the semiconductor substrate 10 and performing exposing and developing steps.

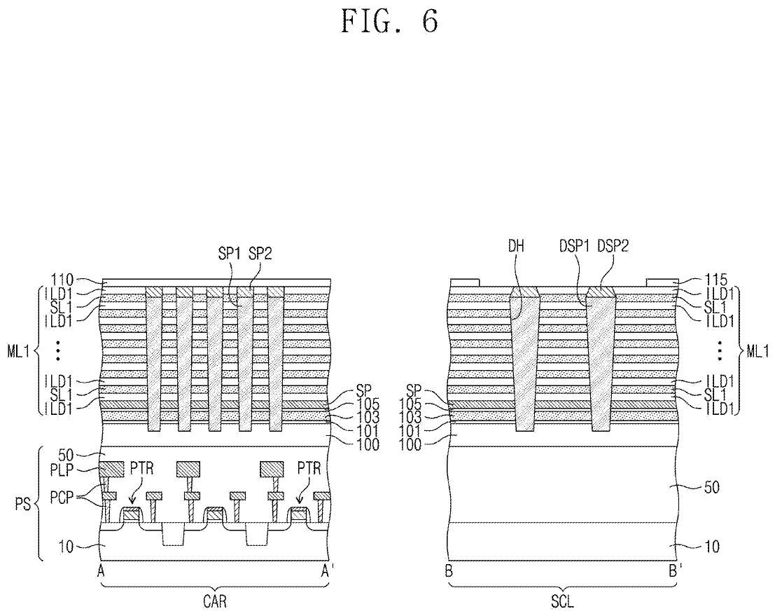

Referring to FIG. 6, the portion of the buffer layer 110 on the scribe line region SCL may be anisotropically etched using the mask pattern MP as an etch mask to expose top surfaces of the second dummy sacrificial pillars DSP2. Thus, a buffer insulating pattern 115 with an opening may be formed on the scribe line region SCL. The buffer layer 110 may cover the first mold structure ML1 and the top surfaces of the second sacrificial pillars SP2 on the cell array region CAR, during the etching process of exposing the top surfaces of the second dummy sacrificial pillars DSP2.

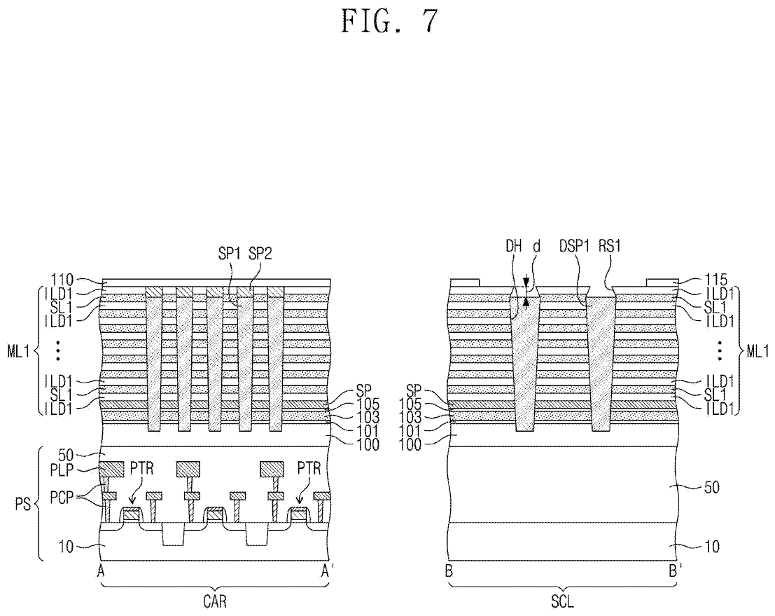

Referring to FIG. 7, if the second dummy sacrificial pillars DSP2 on the scribe line region SCL are exposed, the second dummy sacrificial pillars DSP2 may be removed.

The removal of the second dummy sacrificial pillars DSP2 may include performing an anisotropic or isotropic etching process using an etch recipe having an etch selectivity with respect to the first mold structure ML1 and the first dummy sacrificial pillars DSP1.

As a result of the removal of the second dummy sacrificial pillars DSP2, first recess regions RS1 may be formed to expose a portion of an inner side surface of the dummy hole DH and the top surfaces of the first dummy sacrificial pillars DSP1. The first recess regions RS1 may be formed to expose at least a side surface of the uppermost one of the first interlayer insulating layers ILD1.

In an embodiment of the present inventive concept, a depth d of the first recess regions RS1 (e.g., a height difference between the top surface of the first mold structure ML1 and a bottom surface of the first recess region RS1) may vary depending on a thickness of the second dummy sacrificial pillars DSP2. A height difference d between a top surface of a first mold structure MS1 and the bottom surface of the first recess region RS1 may range from several hundreds of nanometers to several micrometers. The first recess regions RS1, which are formed by the afore-described method, may be used as an alignment key in a subsequent photolithography process.

In an embodiment of the present inventive concept, the buffer layer 110 and the buffer insulating pattern 115 may be removed, after the formation of the first recess regions RS1.

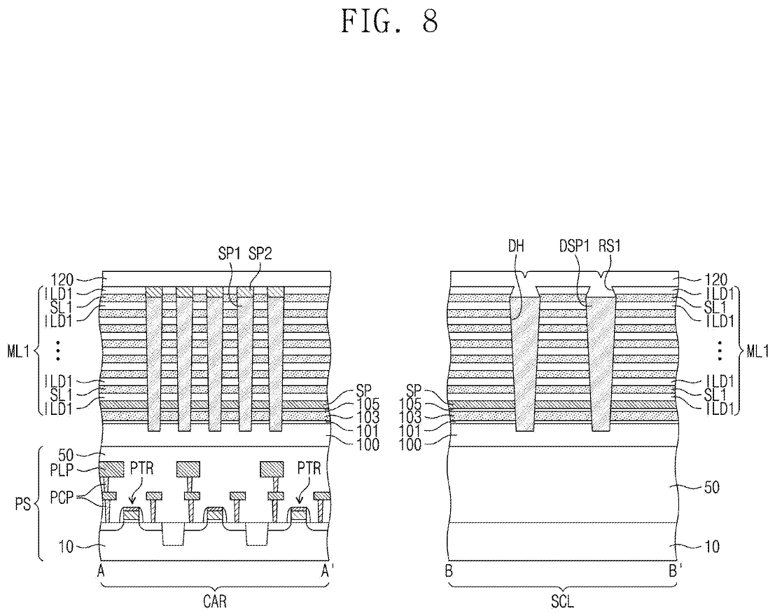

Referring to FIG. 8, after the formation of the first recess regions RS1, an intermediate insulating layer 120 may be formed on the uppermost one of the first interlayer insulating layers ILD1. For example, the intermediate insulating layer 120 may be formed of or include silicon oxide.

The intermediate insulating layer 120 may be deposited using a chemical vapor deposition (CVD) method or an atomic layer deposition (ALD) method on the first mold structure ML1 and may have a substantially uniform thickness on the first mold structure ML1. The intermediate insulating layer 120 may cover the second sacrificial pillars SP2 on the cell array region CAR and may conformally cover the first mold structure ML1 provided with the first recess regions RS1 on the scribe line region SCL.

The thickness of the intermediate insulating layer 120 may be smaller than half of the width of the dummy hole DH. Thus, an uneven structure, which corresponds to the first recess regions RS1, may be formed on a top surface of the intermediate insulating layer 120 in the scribe line region SCL. For example, the top surface of the intermediate insulating layer 120 may have a non-flat profile on the scribe line region SCL.

In an embodiment of the present inventive concept, the formation of the intermediate insulating layer 120 may be omitted.

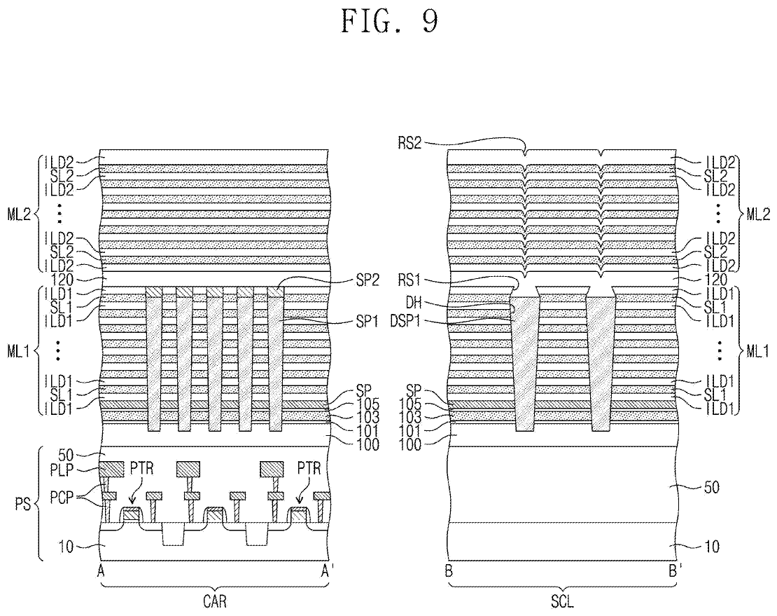

Referring to FIG. 9, a second mold structure ML2 may be formed on the first mold structure ML1.

The second mold structure ML2 may be formed by alternately and repeatedly stacking second interlayer insulating layers ILD2 and second sacrificial layers SL2 on the first mold structure ML1. In an embodiment of the present inventive concept, the second sacrificial layers SL2 may be formed of the same material as the first sacrificial layers SL1 and may have substantially the same thickness as that of the first sacrificial layers SL1.

The formation of the second mold structure ML2 may be substantially the same as the formation of the first mold structure ML1 previously described with reference to FIG. 3. For example, the second sacrificial layers SL2 may be formed of or include an insulating material that is different from that of the second interlayer insulating layers ILD2. The second sacrificial layers SL2 may be formed of or include the same material as the first sacrificial layers SL1. For example, the second sacrificial layers SL2 may be formed of or include silicon nitride, and the second interlayer insulating layers ILD2 may be formed of or include at least one of, for example, silicon oxide, silicon oxynitride, and/or low-k dielectric materials.

Since the second mold structure ML2 is formed using a chemical vapor deposition (CVD) method or an atomic layer deposition (ALD) method to have a uniform thickness, the second mold structure ML2 on the scribe line region SCL may have second recess regions RS2 corresponding to the first recess regions RS1. For example, a top surface of the uppermost one of the second interlayer insulating layers ILD2 may have a non-flat profile on the scribe line region SCL.

In other words, a level of the top surface of the second mold structure ML2 measured from the semiconductor substrate 10 may be lower on the second recess region RS2 than near or away from the second recess region RS2. The level difference of the top surface of the second mold structure ML2 may depend on a depth of the first recess region RS1.

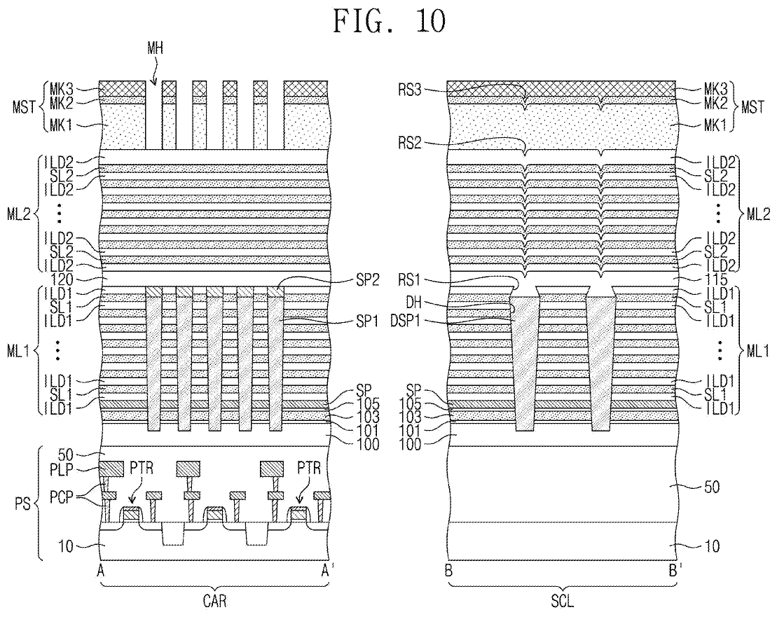

Referring to FIG. 10, a mask structure MST may be formed on the second mold structure ML2. The mask structure MST may include a first mask layer MK1, a second mask layer MK2, and a third mask layer MK3.

For example, the first and second mask layers MK1 and MK2 of the mask structure MST may be formed to have a substantially uniform thickness, using a chemical vapor deposition (CVD) method or an atomic layer deposition (ALD) method. Thus, the first and second mask layers MK1 and MK2 may have top surfaces, in which third recess regions RS3 corresponding to the second recess regions RS2 are formed.

The mask structure MST may be formed of or include materials, which can be preserved without loss or damage during forming upper channel holes of a high aspect ratio on the cell array region CAR.

In an embodiment of the present inventive concept, the first mask layer MK1 may include carbon. The first mask layer MK1 may be, for example, an amorphous carbon layer (ACL) or a spin-on hardmask (SOH) layer, and here, the SOH layer may include a carbon-based SOH layer or a silicon-based SOH layer.

The first mask layer MK1 may be thicker than the second mask layer MK2. The first mask layer MK1 may be formed by a CVD process, which is performed at a high temperature compared to a temperature at which the second mask layer MK2 or the second mold structure ML2 is formed, and thus, the first mask layer MK1 may have relatively high etch selectivity and low transmittance. For example, the first mask layer MK1 may include a hard mask layer.

The second mask layer MK2 may include, for example, silicon nitride or silicon oxynitride, and the third mask layer MK3 may include a photoresist material. For example, the second mask layer MK2 may include an etch stop layer.

Next, referring to FIG. 10, a photolithography process may be performed on the third mask layer MK3. Here, the photolithography process may be a lithography process, in which light of KrF (λ=248 nm), ArF (λ=193 nm), or extreme ultraviolet (EUV) is used as a light source.

In a photolithography process, upper and lower structures should be accurately aligned to each other. For example, to align upper channel holes to lower channel holes in the photolithography process, an optical inspection system may be used to inspect positions of alignment keys. In addition, in the case where the first mask layer MK1 includes carbon, the first mask layer MK1 may absorb an optical signal, which is used to examine the position of the alignment key, and thereby may have low transmittance. In this case, it may be difficult to recognize the first recess regions RS1 (or key patterns), which are formed in the first mold structure ML1.

According to an embodiment of the present inventive concept, when a photolithography process is performed on the third mask layer MK3 in the cell array region CAR, the second recess region RS2 formed in the second mold structure ML2 may be used as the alignment key.

In this case, it may be possible to prevent an invisibility issue of the underlying alignment keys (e.g., the first recess regions RS1 in the first mold structure ML1), which may occur when optical signals cannot reach the first recess regions RS1 in the photolithography process, and in turn to prevent the upper channel holes from being misaligned from the lower channel holes on the cell array region CAR.

For example, in the case where the first mask layer MK1 includes carbon, optical signals, which are used to obtain position information of the alignment key, may be absorbed by the first mask layer MK1 and thus might not reach the first recessed key region RS1 (i.e., the alignment key). However, according to an embodiment of the present inventive concept, it may be possible to prevent a misalignment issue, which occurs in such a case.

As a result of the photolithography process on the third mask layer MK3, the third mask layer MK3 may have openings, which are overlapped with the lower channel holes (i.e., the second sacrificial pillars SP2), in the cell array region CAR.

After the formation of the openings of the third mask layer MK3 in the cell array region CAR, the second and first mask layers MK2 and MK1 may be sequentially and anisotropically etched using the third mask layer MK3 as an etch mask. Thus, mask holes MH may be formed to be overlapped with the lower channel holes (i.e., the second sacrificial pillars SP2).

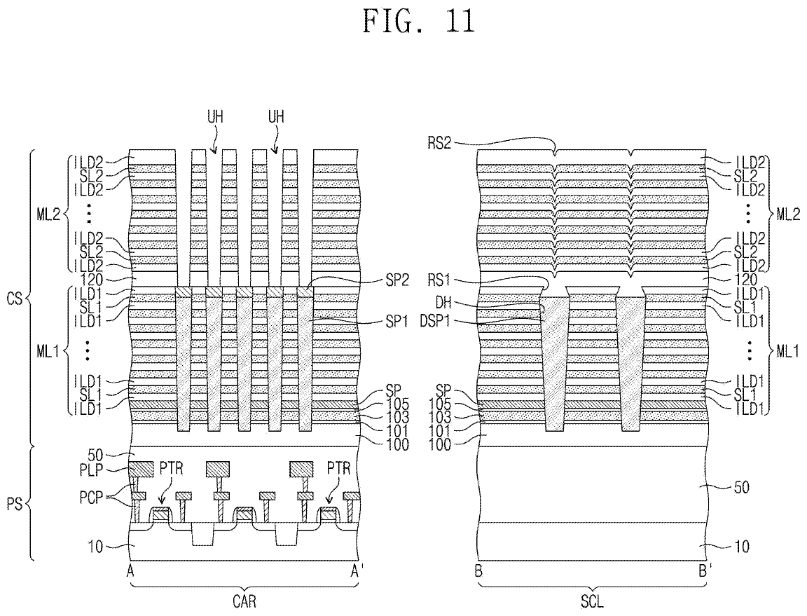

Next, referring to FIG. 11, an anisotropic etching process may be performed on portions of the second mold structure ML2 that are exposed through the mask holes MH. As a result, upper channel holes UH may be formed on the cell array region CAR to penetrate the second mold structure ML2. The upper channel holes UH may be formed to expose the second sacrificial pillars SP2.

The anisotropic etching process on the second mold structure ML2 may be performed using an etch recipe that is capable of successively and anisotropically etching the second interlayer insulating layers ILD2 and the second sacrificial layers SL2. The anisotropic etching process on the second mold structure ML2 may be a dry etching process performed using plasma. When the upper channel holes UH are formed, the second sacrificial pillars SP2 may be used as an etch stop layer.

After the formation of the upper channel holes UH, the mask structure MST may be removed by an ashing process and/or a strip process.

Next, the second sacrificial pillars SP2, which are exposed by the upper channel holes UH, and the first sacrificial pillars SP1 thereunder may be sequentially removed. Thus, vertical channel holes may be formed to penetrate the first and second mold structures ML1 and ML2 and expose the semiconductor layer 100.

The removal of the first and second sacrificial pillars SP1 and SP2 may be performed by an etching process using an etch recipe having an etch selectivity with respect to the first and second mold structures ML1 and ML2.

Each of the vertical channel holes may include a lower channel hole, which is formed to penetrate the first mold structure ML1, and an upper channel hole, which is formed to penetrate the second mold structure ML2 and is connected to the lower channel hole.

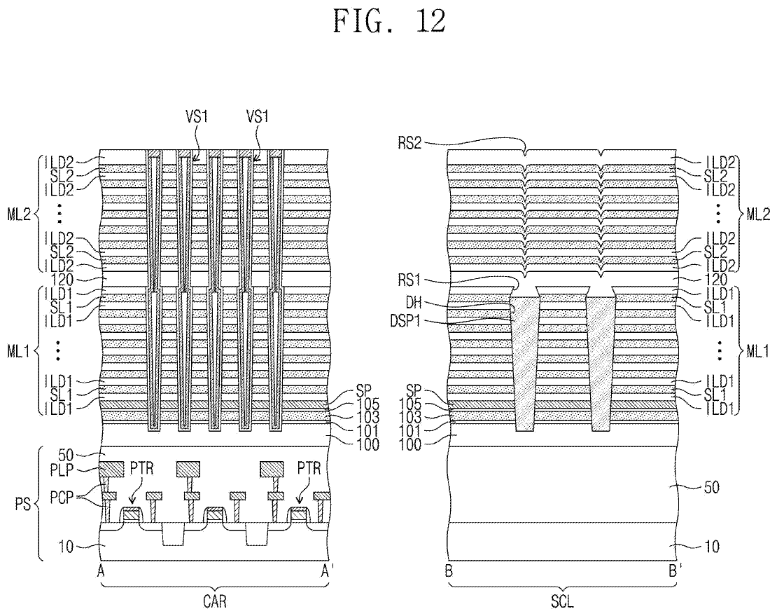

Referring to FIG. 12, vertical structures VS1 may be formed in the vertical channel holes, which are formed to penetrate the first and second mold structures ML1 and ML2, on the cell array region CAR. When the vertical structures VS1 are formed, dummy vertical structures VS2 may be formed on the connection region CNR and may penetrate the first and second mold structures ML1 and ML2.

The formation of the vertical structures VS1 may include sequentially depositing a data storing layer and a vertical semiconductor layer in the vertical channel holes and etching and planarizing the data storing layer and the vertical semiconductor layer on the uppermost one of the second interlayer insulating layers ILD2.

Top surfaces of the vertical structures VS1 may be substantially coplanar with a top surface of the uppermost one of the second interlayer insulating layers ILD2. Each of vertical structures VS may include a first vertical extended portion, which is in the lower channel hole, and a second vertical extended portion, which is in the upper vertical channel hole. The first and second vertical extended portions may be a single object that is continuously extended without any interface therein. For example, the first and second vertical extended portions may be a single body. Here, the first vertical extended portion may have a side surface with a substantially constant slope from bottom to top. Similarly, the second vertical extended portion may have a side surface with a substantially constant slope from bottom to top. For example, as a height from the semiconductor layer 100 increases, a width of each of the first and second vertical extended portions in the first or second direction D1 or D2 may increase. For example, at the level where the first vertical extended portion and the second vertical extend portion are connected to each other, a diameter of the first vertical extended portion may be different from a diameter of the second vertical extended portion. The first and second vertical extended portions may form a stepwise structure at the level where they are connected to each other.

The data storing layer may be conformally deposited on bottom and side surfaces of the vertical channel holes by a chemical vapor deposition (CVD) method or an atomic layer deposition (ALD) method. The data storing layer may include a tunneling insulating layer, a charge storing layer, and a blocking insulating layer, which are sequentially stacked.

The vertical semiconductor layer may be formed using a chemical vapor deposition (CVD) or atomic layer deposition (ALD) method to have a substantially uniform thickness on the data storing layer. The vertical semiconductor layer may be formed of or include at least one of semiconductor materials (e.g., silicon (Si) and germanium (Ge)).

After the formation of the data storing layer and the vertical semiconductor layer, the vertical channel holes may be filled with a gap-fill insulating layer.

Next, bit line conductive pads may be formed in a top portion of the vertical semiconductor layer. The bit line conductive pad may be an impurity-doped region or may be formed of or include at least one of conductive materials. Top surfaces of the bit line conductive pads may be substantially coplanar with a top surface of the uppermost second interlayer insulating layer ILD2.

During the formation of the vertical structures VS1, the second recess region RS2, which is formed in the uppermost one of the second interlayer insulating layers ILD2 in the scribe line region SCL, may have a reduced depth or may be removed.

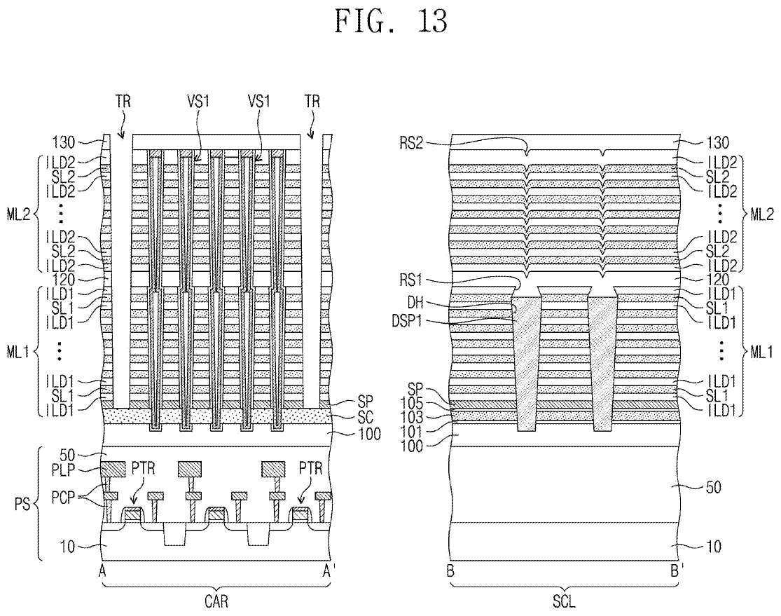

Referring to FIGS. 2 and 13, after the formation of the vertical structures VS1, a first upper insulating layer 130 may be formed to cover the top surfaces of the vertical structures VS1. The first upper insulating layer 130 may cover a top surface of the second mold structure ML2 on the scribe line region SCL.

Next, separation trenches TR may be formed on the cell array region CAR to penetrate the first and second mold structures ML1 and ML2 and expose the support conductive layer SP. For example, the separation trenches TR may penetrate the support conductive layer SP.

The separation trenches TR may be formed by anisotropically etching the first upper insulating layer 130 and the first and second mold structures ML1 and ML2, and the support conductive layer SP may be used as an etch stop layer in the anisotropic etching process.

The separation trenches TR may be extended in the first direction D1. Some of the separation trenches TR may be extended from the cell array region CAR to the connection region CNR in the first direction D1.

After the formation of the separation trenches ST, a replacement process may be performed to replace the first insulating layer 101, the second insulating layer 103, and the third insulating layer 105 on the cell array region CAR with a source conductive pattern SC.

The formation of the source conductive pattern SC may include performing an isotropic etching process on the second insulating layer 103 and the first and second insulating layers 101 and 105 that are exposed by the separation trenches ST. During the isotropic etching process, portions of the data storing layer may also be isotropically etched to partially expose the vertical semiconductor layer. Thereafter, a doped poly silicon layer may be deposited to form the source conductive pattern SC.

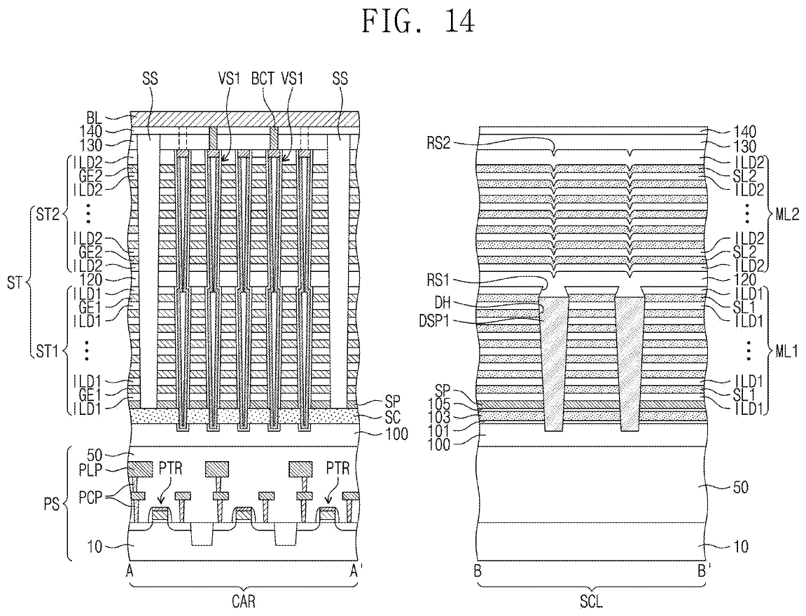

Referring to FIGS. 2 and 14, after the formation of the source conductive pattern SC, a stack ST may be formed by performing replacement processes to replace the first and second sacrificial layers SL1 and SL2 on the cell array region CAR with first and second conductive patterns GE1 and GE2. The stack ST may be extended from the cell array region CAR to the connection region CNR in the first direction D1 and may have a stepwise structure on the connection region CNR.

The formation of the stack ST may include isotropically etching the first and second sacrificial layers SL1 and SL2 using an etch recipe to form gate regions between the first and second interlayer insulating layers ILD1 and ILD2, and forming the first and second conductive patterns GE1 and GE2 in the gate regions. The etch recipe may have an etch selectivity with respect to the first and second interlayer insulating layers ILD1 and ILD2, the vertical structures VS1, and the source conductive pattern SC.

In an embodiment of the present inventive concept, the first and second conductive patterns GE1 and GE2 may be formed of or include at least one of doped semiconductor materials (e.g., doped silicon), metallic materials (e.g., tungsten, molybdenum, nickel, copper, and aluminum), conductive metal nitride materials (e.g., titanium nitride and tantalum nitride), or transition metals (e.g., titanium and tantalum).

The stack ST may include a first stack ST1, in which the first interlayer insulating layers ILD1 and the first conductive patterns GE1 are alternately stacked on each other, and a second stack ST2, in which the second interlayer insulating layers ILD2 and the second conductive patterns GE2 are alternately stacked on each other.

Each of the first and second conductive patterns GE1 and GE2 may include a pad portion in a connection region CNR1, and cell contact plugs CPLG may be coupled to the pad portions of the first and second conductive patterns GE1 and GE2.

The first and second mold structures ML1 and ML2 may remain on the scribe line region SCL, during the formation of the stack ST on the cell array region CAR and the connection region CNR.

After the formation of the first and second conductive patterns GE1 and GE2, separation structures SS may be formed by filling the separation trenches ST with an insulating material.

Next, a second upper insulating layer 140 may be formed on the first upper insulating layer 130, and bit line contact plugs BCT, which are connected to the vertical structures VS, may be formed in the cell array region CAR. The bit line contact plugs BCT may be formed of or include at least one of metallic materials and/or metal nitride materials.

Bit lines BL may be formed on the second upper insulating layer 140 and may be connected to the bit line contact plugs BCT. The bit lines BL may be extended in the second direction D2 to cross the stack ST.

Accordingly, a cell array structure CS may be formed on the peripheral circuit structure PS.

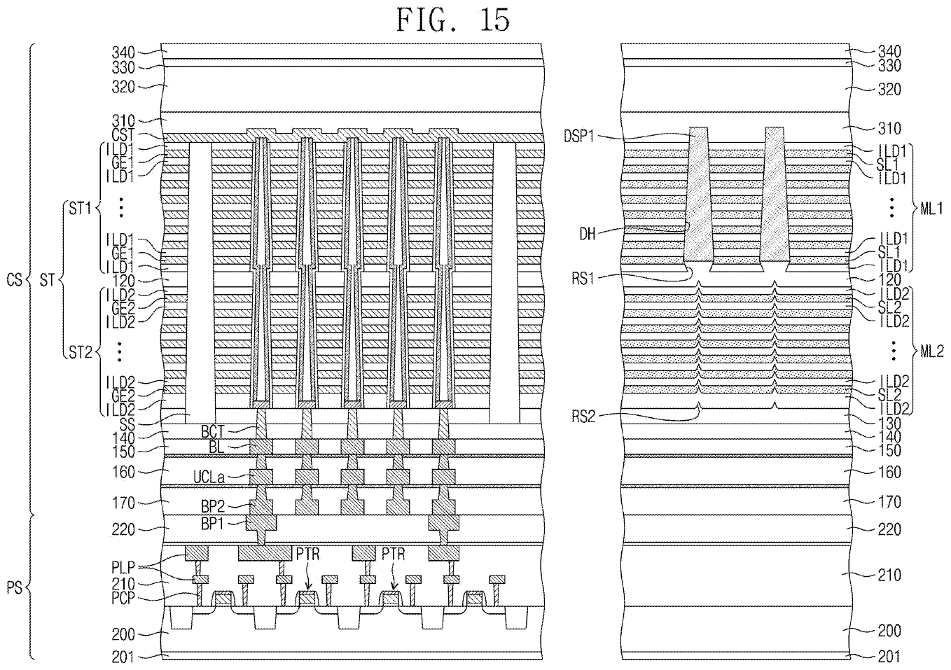

FIG. 15 is a sectional view illustrating a semiconductor device according to an embodiment of the present inventive concept.

Referring to FIG. 15, a semiconductor device according to an embodiment of the present inventive concept may include the peripheral circuit structure PS, which is on a semiconductor substrate 200, and the cell array structure CS, which is on the peripheral circuit structure PS. The semiconductor substrate 200 may include the cell array region CAR and the scribe line region SCL.

In an embodiment of the present inventive concept, since the cell array structure CS is placed on the peripheral circuit structure PS, a cell capacity per unit area in the semiconductor memory device may be increased. In addition, the peripheral circuit structure PS and the cell array structure CS may be separately fabricated and then may be coupled to each other, and in this case, it may be possible to prevent the peripheral circuits PTR from being damaged by several thermal treatment processes. Accordingly, the semiconductor memory device may have improved electrical and reliability characteristics.

For example, the peripheral circuit structure PS may be formed on the semiconductor substrate 200 and may include the peripheral circuits PTR, which control the cell array structure CS, and peripheral interlayer insulating layers 210 and 220, which cover the peripheral circuits PTR. The peripheral circuits PTR may be integrated on a top surface of the semiconductor substrate 200. A surface insulating layer 201 may be provided on a bottom or rear surface of the semiconductor substrate 200.

The peripheral circuits PTR may include NMOS and PMOS transistors, which are integrated on the top surface of the semiconductor substrate 200. The peripheral circuit lines PLP may be electrically connected to the peripheral circuits PTR through the peripheral contact plugs PCP. The peripheral circuits PTR may include row and column decoders, a page buffer, a control circuit, and so forth.

In an embodiment of the present inventive concept, widths of the peripheral contact plugs PCP in the first or second direction D1 or D2 may increase as a height in a third direction D3 increases. Peripheral contact plugs PCP and the peripheral circuit lines PLP may be formed of or include at least one of conductive materials (e.g., metallic materials).

The peripheral interlayer insulating layers 210 and 220 may be provided on a top surface of the semiconductor substrate 200. The peripheral interlayer insulating layers 210 and 220 may cover the peripheral circuits PTR, the peripheral contact plugs PCP, and the peripheral circuit lines PLP, on the semiconductor substrate 200. The peripheral contact plugs PCP and the peripheral circuit lines PLP may be electrically connected to the peripheral circuits PTR. The peripheral interlayer insulating layers 210 and 220 may include, for example, a silicon oxide layer, a silicon nitride layer, a silicon oxynitride layer, and/or a low-k dielectric layer.

First bonding pads BP1 may be disposed in the peripheral interlayer insulating layer 220. For example, the first bonding pads BP1 may be disposed in the uppermost portion of the peripheral interlayer insulating layer 220. The peripheral interlayer insulating layer 220 might not cover top surfaces of the first bonding pads BP1. A top surface of the peripheral interlayer insulating layer 220 may be substantially coplanar with the top surfaces of the first bonding pads BP1. The first bonding pads BP1 may be electrically connected to the peripheral circuits PTR through the peripheral circuit lines PLP and the peripheral contact plugs PCP.

The cell array structure CS may be provided on the peripheral circuit structure PS. The cell array structure CS of the semiconductor memory device may include the cell array region CAR and connection region.

The cell array structure CS may include a memory cell array, in which memory cells are three-dimensionally arranged.

The cell array structure CS may include a source conductive pattern CST, the stack ST, the first and second mold structures ML1 and ML2, the vertical structures VS1, VS2, the first dummy sacrificial pillars DSP1, the bit lines BL, the cell contact plugs CPLG, and second bonding pads BP2.

The cell array structure CS may include a plurality of stacks ST. The stacks ST may be extended in the first direction D1 and may be spaced apart from each other in the second direction D2, when viewed in the plan view of FIG. 2. Hereinafter, just one of the stacks ST will be described, for brevity's sake, but the others of the stacks ST may also have substantially the same features as described below.

The stack ST may include the first stack ST1 and the second stack ST2 on the first stack ST1, as described above.

As described above, the first stack ST1 may include first interlayer insulating layers ILD1 and first conductive patterns GE1, which are alternately stacked on top of another, and the second stack ST2 may include second interlayer insulating layers ILD2 and second conductive patterns GE2, which are alternately stacked on top of another.

In an embodiment of the present inventive concept, the second stack ST2 may be disposed between the first stack ST1 and the peripheral circuit structure PS. For example, the second stack ST2 may be provided on a bottom surface of the lowermost one of the first interlayer insulating layers ILD1 of the first stack ST1. For example, the uppermost one of the second interlayer insulating layers ILD2 of the second stack ST2 may be in contact with the lowermost one of the first interlayer insulating layers ILD1 of the first stack ST1, but the present inventive concept is not limited to this example. For example, a single insulating layer may be provided between the uppermost one of the second conductive patterns GE2 of the second stack ST2 and the first conductive patterns GE1 of the first stack ST1.

The source conductive pattern CST may be disposed on the uppermost one of the first interlayer insulating layers ILD1 of the first stack ST1. The source conductive pattern CST may have a substantially uniform thickness and may have a substantially flat top surface. In the cell array region CAR and the first connection region CNR1, the source conductive pattern CST may be extended parallel to the stack ST or in the first direction D1. When measured in the first direction D1, a length of the source conductive pattern CST may be larger than a length of the uppermost one of the first conductive patterns GE1 of the first stack ST1.

The source conductive pattern CST may be formed of or include at least one of, for example, doped semiconductor materials (e.g., doped silicon), metallic materials (e.g., tungsten, molybdenum, nickel, copper, and aluminum), conductive metal nitrides (e.g., titanium nitride and tantalum nitride), or transition metals (e.g., titanium and tantalum). In an embodiment of the present inventive concept, the source conductive pattern CST may be formed of or include at least one of metallic materials (e.g., tungsten).

An upper insulating layer 310 may cover the source conductive pattern CST. A capping insulating layer 320 and a passivation layer 340 may be sequentially formed to cover the upper insulating layer 310. The capping insulating layer 320 may be, for example, a silicon nitride layer or a silicon oxynitride layer. The passivation layer 340 may be formed of or include polyimide-based materials (e.g., photo sensitive polyimide (PSPI)).

In an embodiment of the present inventive concept, the first and second mold structures ML1 and ML2 may be disposed in the scribe line region SCL, and the second mold structure ML2 may be disposed between the first mold structure ML1 and the peripheral circuit structure PS. The first and second mold structures ML1 and ML2 may include the first and second sacrificial layers SL1 and SL2, which are located at the same levels as the first and second conductive patterns GE1 and GE2, respectively.

The first mold structure ML1 may have a first recess region RS1, which is defined by an inner side surface of the dummy hole DH and a bottom surface of the first dummy sacrificial pillar DSP1, as described above.

The second mold structure ML2 may have the second recess region RS2, as described above. Here, the second recess region RS2 may have a concave profile toward the first dummy sacrificial pillar DSP1.

The vertical structure VS may be provided on the cell array region CAR to penetrate the stack ST and may be connected to the source conductive pattern CST. The vertical structures VS may be arranged in a specific direction or in a zigzag shape, when viewed in a plan view. For example, the vertical structures VS may be arranged with an alternating arrangement. The vertical structures VS may be provided on the connection region CNR and may penetrate end portions (e.g., the pad portions) of the first and second conductive patterns GE1 and GE2.

The vertical structures VS1 may be extended in the third direction D3, which is substantially perpendicular to the top surface of the semiconductor substrate 200, to penetrate the stack ST and may be connected to the source conductive pattern CST. Each of the vertical structures VS may be provided in a vertical channel hole, which is formed to penetrate the stack ST. In an embodiment of the present inventive concept, the vertical channel hole may include a first vertical channel hole, which is formed to penetrate the first stack ST1, and a second vertical channel hole, which is formed to penetrate the second stack ST2 and be connected to the first vertical channel hole.

The top surfaces of the vertical structures VS1 may be located at a level higher than a top surface of the uppermost one of the interlayer insulating layers ILD1. Each of the vertical structures VS may include a vertical channel pattern, a data storage pattern, and a vertical insulating pillar. The vertical channel pattern may be formed of or include at least one of semiconductor materials (e.g., silicon (Si) and germanium (Ge)). The vertical channel pattern may be connected to the source conductive pattern CST. For example, the vertical channel pattern may be in contact with the source conductive pattern CST.

In the scribe line region SCL, the first dummy sacrificial pillar DSP1 may be provided to penetrate a portion of the first mold structure ML1 When measured from the top surface of the semiconductor substrate 200, the bottom surface of the first dummy sacrificial pillar DSP1 may be located at a level higher than a bottom surface of the first mold structure ML1 (e.g., a bottom surface of a lowermost one of the first interlayer insulating layer ILD1).

In the cell array region CAR, the bit lines BL may be disposed on the second upper insulating layer 140. The bit lines BL may be extended in the second direction D2 to cross the stack ST. The bit lines BL may be electrically connected to the vertical structures VS1 through the bit line contact plugs BCT.

Third and fourth upper insulating layers 150 and 160 may be disposed on the second upper insulating layer 140. Upper conductive lines UCLa may be disposed in the fourth upper insulating layer 160. The upper conductive lines UCLa may be electrically connected to the bit lines BL, in the cell array region CAR.

The upper conductive lines UCLa may be formed of or include at least one of, for example, metallic materials (e.g., tungsten, copper, and aluminum), conductive metal nitride materials (e.g., titanium nitride and tantalum nitride), or transition metals (e.g., titanium and tantalum). In an embodiment of the present inventive concept, the bit lines BL may be formed of or include a material (e.g., tungsten) having relatively high electric resistivity, and the first upper conductive lines UCLa may be formed of or include a material (e.g., copper) having relatively low electric resistivity.

A fifth upper insulating layer 170 may be disposed on the fourth upper insulating layer 160, and the second bonding pads BP2 may be disposed in the fifth upper insulating layer 170. In an embodiment of the present inventive concept, the second bonding pads BP2 may be formed in the uppermost one of the upper insulating layers (e.g., the fifth upper insulating layer 170). The second bonding pads BP2 may be electrically connected to the first upper conductive lines UCLa. The second bonding pads BP2 may be formed of or include, for example, aluminum, copper, or tungsten.

The second bonding pads BP2 may be electrically and physically connected to the first bonding pads BP1 by a bonding method. For example, the second bonding pads BP2 may be in direct contact with the first bonding pads BP1.

The second bonding pads BP2 may be formed of or include the same metallic material as that of the first bonding pads BP1. The second bonding pads BP2 may be substantially the same as the first bonding pads BP1 in terms of shape, width, or area.

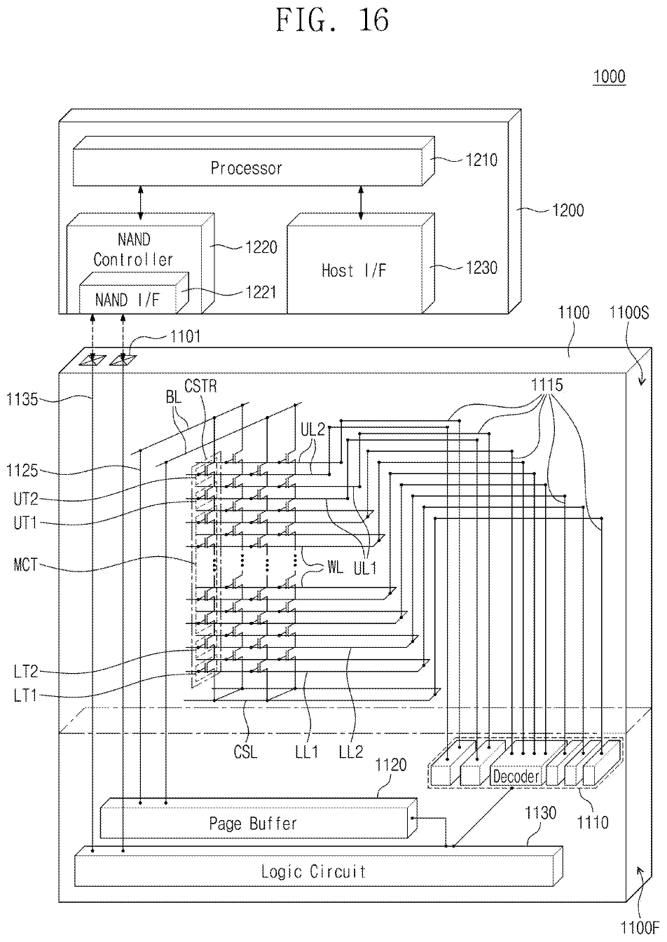

FIG. 16 is a diagram schematically illustrating an electronic system, which includes a semiconductor device according to an embodiment of the present inventive concept.

Referring to FIG. 16, an electronic system 1000 according to an embodiment of the present inventive concept may include a semiconductor device 1100 and a controller 1200, which is electrically connected to the semiconductor device 1100. The electronic system 1000 may be a storage device, which includes one or more semiconductor devices 1100, or an electronic device including the storage device. For example, the electronic system 1000 may be a solid state drive (SSD) device, a universal serial bus (USB), a computing system, a medical system, or a communication system, in which at least one semiconductor device 1100 is provided.

The semiconductor device 1100 may be a nonvolatile memory device (e.g., a NAND FLASH memory device). The semiconductor device 1100 may include a first structure 1100F and a second structure 1100S on the first structure 1100F. In an embodiment of the present inventive concept, the first structure 1100F may be disposed near the second structure 1100S.

The first structure 1100F may be a peripheral circuit structure, which includes a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2, which are adjacent to the common source line CSL, upper transistors UT1 and UT2, which are adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously changed, according to embodiments of the present inventive concept.

In an embodiment of the present inventive concept, the upper transistors UT1 and UT2 may include at least one string selection transistor, and the lower transistors LT1 and LT2 may include at least one ground selection transistor. The gate lower lines LL1 and LL2 may be used as gate electrodes of the lower transistors LT1 and LT2, respectively. The word lines WL may be used as gate electrodes of the memory cell transistors MCT, and the gate upper lines UL1 and UL2 may be used as gate electrodes of the upper transistors UT1 and UT2, respectively.

In an embodiment of the present inventive concept, the lower transistors LT1 and LT2 may include a lower erase control transistor LT1 and a ground selection transistor LT2, which are connected to each other in series. The upper transistors UT1 and UT2 may include a string selection transistor UT1 and an upper erase control transistor UT2, which are connected to each other in series. At least one of the lower and upper erase control transistors LT1 and UT2 may be used to perform an erase operation of erasing data in the memory cell transistors MCT using a gate-induced drain leakage (GIDL) phenomenon.

The common source line CSL, the first and second gate lower lines LL1 and LL2, the word lines WL, and the first and second gate upper lines UL1 and UL2 may be electrically connected to the decoder circuit 1110 through first connection lines 1115, which are extended from the first structure 1100F to the second structure 1100S. The bit lines BL may be electrically connected to the page buffer 1120 through second connection lines 1125, which are extended from the first structure 1100F to the second structure 1100S.

In the first structure 11001F, the decoder circuit 1110 and the page buffer 1120 may be configured to perform a control operation on at least one transistor that is selected from the memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection line 1135, which is provided in the first structure 1100F and is extended into the second structure 1100S.

The first structure 1100F may include a voltage generator. The voltage generator may generate a program voltage, a read voltage, a pass voltage, a verification voltage, and so forth, which are used for operating the memory cell strings CSTR. Here, the program voltage may be a relatively high voltage (e.g., about 20V to about 40V), compared with the read voltage, the pass voltage, and the verification voltage.

In an embodiment of the present inventive concept, the first structure 1100F may include high voltage transistors and low voltage transistors. The decoder circuit 1110 may include pass transistors which are connected to the word lines WL of the memory cell strings CSTR. The pass transistors may include high-voltage transistors which can stand a high voltage (e.g., the program voltage) applied to the word lines WL during a programming operation). The page buffer 1120 may also include high-voltage transistors which can stand the high voltage.

The controller 1200 may include a processor 1210, a NAND controller 1220, and a host interface 1230. In an embodiment of the present inventive concept, the electronic system 1000 may include a plurality of semiconductor devices 1100, and in this case, the controller 1200 may control the semiconductor devices 1100.

The processor 1210 may control overall operations of the electronic system 1000 including the controller 1200. The processor 1210 may be operated based on a specific firmware and may control the NAND controller 1220 to access the semiconductor device 1100. The NAND controller 1220 may include a NAND interface 1221, which is used to communicate with the semiconductor device 1100. The NAND interface 1221 may be used to transmit and receive control commands, which are for controlling the semiconductor device 1100, and data, which is to be written in or read from the memory cell transistors MCT of the semiconductor device 1100. The host interface 1230 may be configured to allow for communication between the electronic system 1000 and an external host. When a control command is received from an external host through the host interface 1230, the processor 1210 may control the semiconductor device 1100 in response to the control command.

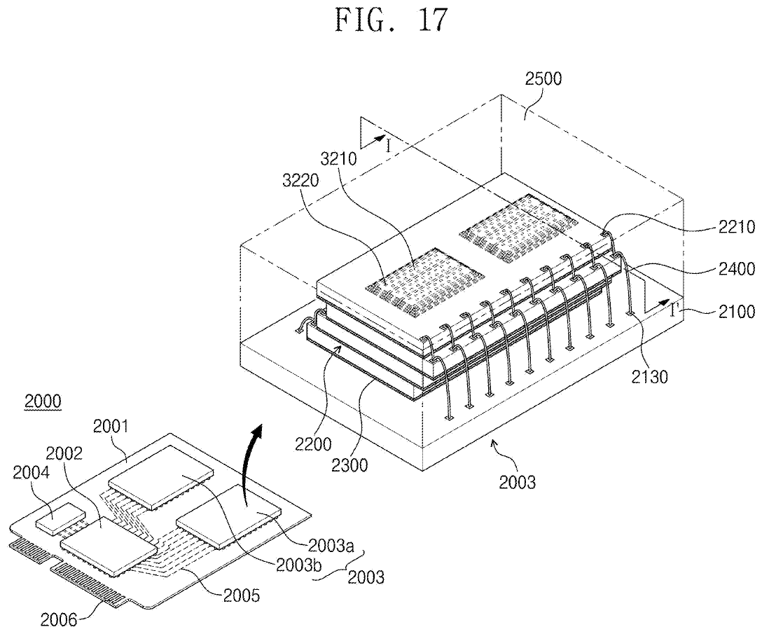

FIG. 17 is a perspective view schematically illustrating an electronic system, which includes a semiconductor device according to an embodiment of the present inventive concept.

Referring to FIG. 17, an electronic system 2000 according to an embodiment of the present inventive concept may include a main substrate 2001 and a controller 2002, at least one semiconductor package 2003, and a DRAM 2004, which are mounted on the main substrate 2001. The semiconductor package 2003 and the DRAM 2004 may be connected to the controller 2002 through interconnection patterns 2005, which are formed in the main substrate 2001.

The main substrate 2001 may include a connector 2006, which includes, for example, a plurality of pins coupled to an external host. In the connector 2006, the number and arrangement of the pins may depend on a communication interface between the electronic system 2000 and the external host. In an embodiment of the present inventive concept, the electronic system 2000 may communicate with the external host, in accordance with one of interfaces, such as universal serial bus (USB), peripheral component interconnect express (PCI-Express), serial advanced technology attachment (SATA), universal flash storage (UFS) M-Phy, or the like. In an embodiment of the present inventive concept, the electronic system 2000 may be driven by a power, which is supplied from the external host through the connector 2006. The electronic system 2000 may further include a power management integrated circuit (PMIC) that is configured to separately supply an electric power, which is supplied from the external host, to the controller 2002 and the semiconductor package 2003.

The controller 2002 may be configured to control a writing or reading operation on the semiconductor package 2003 and to increase an operation speed of the electronic system 2000.

The DRAM 2004 may be a buffer memory that is configured to relieve technical difficulties caused by a difference in speed between the semiconductor package 2003, which serves as a data storage device, and an external host. In an embodiment of the present inventive concept, the DRAM 2004 in the electronic system 2000 may serve as a cache memory and may be used as a storage space, which is used to temporarily store data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 respectively disposed on bottom surfaces of the semiconductor chips 2200, a connection structure 2400 electrically connecting the semiconductor chips 2200 to the package substrate 2100, and a molding layer 2500 disposed on the package substrate 2100 to cover the semiconductor chips 2200 and the connection structure 2400.

The package substrate 2100 may be a printed circuit board including upper pads 2130. Each of the semiconductor chips 2200 may include an input/output pad 2210. The input/output pad 2210 may correspond to the input/output pad 1101 of FIG. 16. Each of the semiconductor chips 2200 may include stacks 3210 and vertical structures 3220. Each of the semiconductor chips 2200 may include a semiconductor device, which will be described below, according to an embodiment of the present inventive concept.

In an embodiment of the present inventive concept, the connection structure 2400 may include a bonding wire electrically connecting the input/output pad 2210 to the upper pads 2130. Thus, in each of the first and second semiconductor packages 2003a and 2003b, the semiconductor chips 2200 may be electrically connected to each other in a bonding wire manner and may be electrically connected to the upper pads 2130 of the package substrate 2100. In an embodiment of the present inventive concept, the semiconductor chips 2200 in each of the first and second semiconductor packages 2003a and 2003b may be electrically connected to each other by a connection structure including through silicon vias (TSVs), not by the connection structure 2400 provided in the form of bonding wires.

In an embodiment of the present inventive concept, the controller 2002 and the semiconductor chips 2200 may be included in a single package. In an embodiment of the present inventive concept, the controller 2002 and the semiconductor chips 2200 may be mounted on a separate interposer substrate, which is prepared regardless of the main substrate 2001, and may be connected to each other through interconnection lines, which are provided in the interposer substrate.

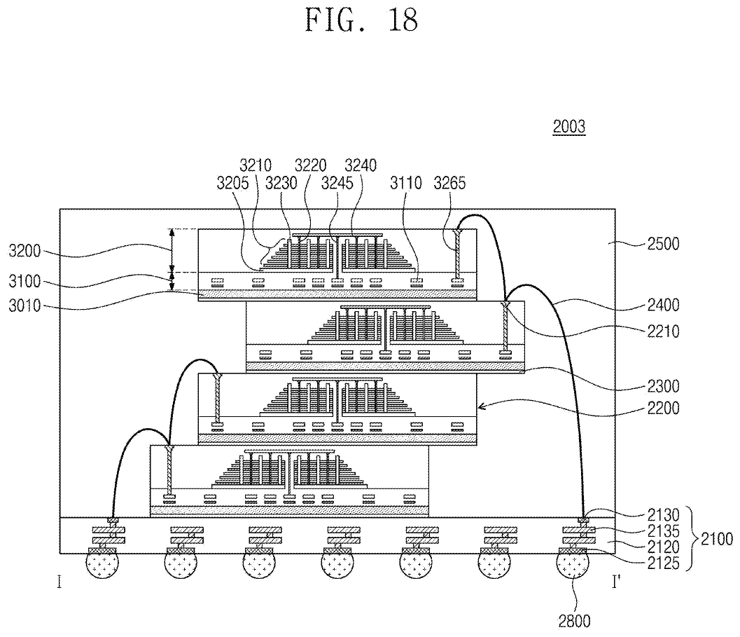

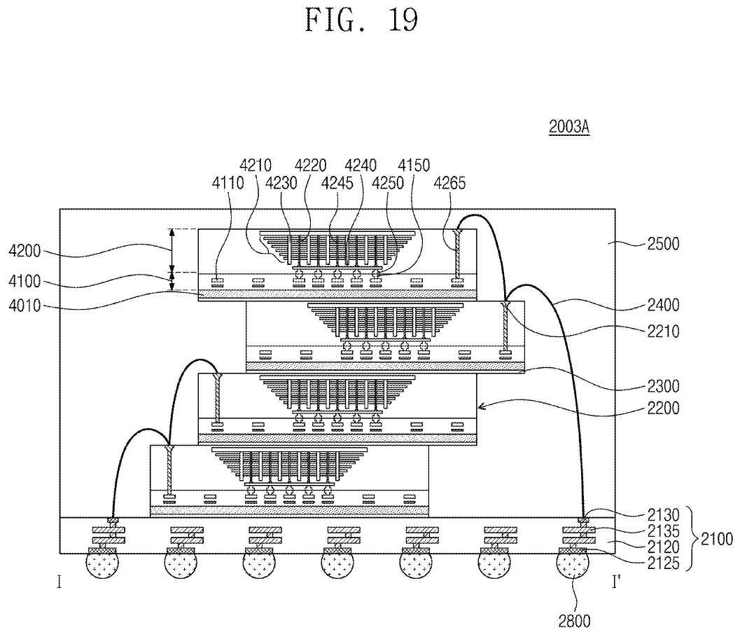

FIGS. 18 and 19 are sectional views illustrating semiconductor packages according to some embodiments of the present inventive concept and schematically illustrating a portion of the semiconductor package taken along the line I-I′ of FIG. 2.

Referring to FIG. 18, in the semiconductor package 2003, the package substrate 2100 may be a printed circuit board. The package substrate 2100 may include a package substrate body portion 2120, the upper pads 2130 (e.g., of FIG. 2), which are disposed on a top surface of the package substrate body portion 2120, lower pads 2125, which are disposed on or exposed through a bottom surface of the package substrate body portion 2120, and internal lines 2135, which are provided in the package substrate body portion 2120 to electrically connect the upper pads 2130 to the lower pads 2125. The upper pads 2130 may be electrically connected to the connection structures 2400. The lower pads 2125 may be connected to the interconnection patterns 2005 of the main substrate 2001 of the electronic system 2000 through conductive connecting portions 2800.

Each of the semiconductor chips 2200 may include a semiconductor substrate 3010 and first and second structures 3100 and 3200, which are sequentially stacked on the semiconductor substrate 3010. The first structure 3100 may include a peripheral circuit region, in which peripheral lines 3110 are provided. The second structure 3200 may include a source structure 3205, a stack 3210 on the source structure 3205, the vertical structures 3220 and separation structures penetrating the stack 3210, bit lines 3240 electrically connected to the vertical structures 3220, and cell contact plugs 3235 electrically connected to the word lines WL (e.g., of FIG. 1) of the stack 3210. Each of the first and second structures 3100 and 3200 and the semiconductor chips 2200 may further include separation structures to be described below.

Each of the semiconductor chips 2200 may include penetration lines 3245, which are electrically connected to the peripheral lines 3110 of the first structure 3100 and are extended into the second structure 3200. The penetration line 3245 may be disposed outside the stack 3210, and in an embodiment of the present inventive concept, the penetration line 3245 may be provided to further penetrate the stack 3210. Each of the semiconductor chips 2200 may further include the input/output pads 2210 (e.g., of FIG. 2), which are electrically connected to the peripheral lines 3110 of the first structure 3100.

Referring to FIG. 19, in a semiconductor package 2003A, each of the semiconductor chips 2200 may include a semiconductor substrate 4010, a first structure 4100 on the semiconductor substrate 4010, and a second structure 4200, which is provided on the first structure 4100 and is bonded with the first structure 4100 in a wafer bonding manner.

The first structure 4100 may include a peripheral circuit region, in which a peripheral line 4110 and first junction structures 4150 are provided. The second structure 4200 may include a source structure 4205, a stack 4210 between the first structure 4100 and the source structure 4205, vertical structures 4220 and a separation structure penetrating the stack 4210, and second junction structures 4250, which are electrically and respectively connected to the vertical structures 4220 and the word lines WL (e.g., see FIG. 1) of the stack 4210. For example, the second junction structures 4250 may be electrically and respectively connected to the vertical structures 4220 and the word lines WL (e.g., of FIG. 1) through bit lines 4240, which are electrically connected to the vertical structures 4220, and cell contact plugs 4235, which are electrically connected to the word lines WL (e.g., of FIG. 1). The first junction structures 4150 of the first structure 4100 may be in contact with and bonded to the second junction structures 4250 of the second structure 4200. The bonded portions of the first and second junction structures 4150 and 4250 may be formed of or include, for example, copper (Cu).

Each of the first and second structures 4100 and 4200 and the semiconductor chips 2200 may further include a source structure in an embodiment of the present inventive concept that is to be described below. Each of the semiconductor chips 2200 may further include the input/output pads 2210 (e.g., of FIG. 17), which are electrically connected to the peripheral lines 4110 of the first structure 4100.

The semiconductor chips 2200 of FIG. 18 or 19 may be electrically connected to each other by the connection structures 2400, which are provided in the form of bonding wires. However, in an embodiment of the present inventive concept, semiconductor chips, which are provided in the same semiconductor package as the semiconductor chips 2200 of FIG. 18 or 19, may be electrically connected to each other by a connection structure including through silicon vias (TSVs).

The first structure 3100 or 410 of FIG. 18 or 19 may correspond to the peripheral circuit structure in the afore-described embodiments, and the second structure 3200 or 4200 of FIG. 18 or 19 may correspond to the cell array structure in the afore-described embodiments.

According to an embodiment of the present inventive concept, a recessed key region, which has a controllable height, may be formed in a dummy hole of a first mold structure. Thus, even when a channel hole of a high aspect ratio is formed, a height difference in an alignment key may be preserved, and thus, it may be possible to prevent a misalignment issue from occurring between a lower channel hole and an upper channel hole.

As a result, it may be possible to reduce a process defect in a process of fabricating a semiconductor device and increase productivity and reliability of the semiconductor device.

While the present inventive concept has been particularly shown and described with reference to example embodiments thereof, it will be apparent to those of ordinary skill in the art that various changes in form and detail may be made thereto without departing from the spirit and scope of the present inventive concept.

What is claimed is:

1. A method of fabricating a semiconductor device, comprising:
alternately stacking first interlayer insulating layers and first sacrificial layers on a substrate to form a first mold structure;
forming a dummy hole penetrating the first mold structure;
forming a dummy sacrificial pillar in the dummy hole, wherein the formation of the dummy sacrificial pillar comprises forming a first recessed key region to expose a portion of an inner side surface of the dummy hole; and
forming a second mold structure with a substantially uniform thickness on the first recessed key region and the first mold structure,
wherein a top surface of the second mold structure has a second recessed key region corresponding to the first recessed key region.

2. The method of claim 1, wherein the forming of the dummy sacrificial pillar comprises:
sequentially forming a first dummy sacrificial pillar and a second dummy sacrificial pillar in the dummy hole; and
removing the second dummy sacrificial pillar such that a top surface of the first dummy sacrificial pillar is exposed.

3. The method of claim 2, wherein the first dummy sacrificial pillar comprises a first metal material, and
the second dummy sacrificial pillar comprises a second metal material having an etch selectivity with respect to the first metal material.

4. The method of claim 3, wherein each of the first and second metal materials has an etch selectivity with respect to each of the first interlayer insulating layers and the first sacrificial layers.

5. The method of claim 1, further comprising sequentially forming a first mask layer, a second mask layer, and a third mask layer on the second mold structure,
wherein a top surface of each of the first and second mask layers has a third recessed key region overlapping the second recessed key region.

6. The method of claim 5, wherein a thickness of the first mask layer is larger than a thickness of the second mask layer, and
the first mask layer is formed at a temperature higher than a temperature at which the second mask layer is formed.

7. The method of claim 5, wherein the first mask layer comprises carbon (C).

8. The method of claim 1, wherein the substrate comprises a chip region and a scribe line region, and
the first and second recessed key regions are provided in the scribe line region.

9. The method of claim 8, further comprising:
forming lower channel holes on the chip region and penetrating the first mold structure;
sequentially forming a first sacrificial pillar and a second sacrificial pillar in each of the lower channel holes; and
forming upper channel holes on the chip region and penetrating the second mold structure, wherein the upper channel holes expose the second sacrificial pillars in the lower channel holes, respectively,
wherein the forming of the upper channel holes comprises patterning the second mold structure using the second recessed key region as an alignment key.

10. The method of claim 9, wherein the first and second sacrificial pillars are formed of materials, which have an etch selectivity with respect to the first and second mold structures and are different from each other.

11. The method of claim 9, wherein a top surface of the first sacrificial pillar is located at a level lower than a top surface of the first mold structure.

12. A method of fabricating a semiconductor device, comprising:
providing a substrate including a first region and a second region;
alternately stacking first interlayer insulating layers and first sacrificial layers on the substrate to form a first mold structure;
forming lower channel holes and dummy holes penetrating the first mold structure, wherein the lower channel holes and the dummy holes are provided on the first region and the second region, respectively;
sequentially forming first and second sacrificial pillars in each of the lower channel holes;
sequentially forming first and second dummy sacrificial pillars in each of the dummy holes;
removing the second dummy sacrificial pillar from the second region to form a first recessed key region exposing a portion of an inner side surface of each of the dummy holes;
alternately stacking second interlayer insulating layers and second sacrificial layers on the first mold structure to form a second mold structure, wherein a top surface of the second mold structure in the second region has a second recessed key region overlapping to the first recessed key region; and
forming upper channel holes on the first region and penetrating the second mold structure, wherein the upper channel holes expose the second sacrificial pillars in the lower channel holes, respectively,
wherein the forming of the upper channel holes comprises patterning the second mold structure using the second recessed key region as an alignment key.

13. The method of claim 12, further comprising forming a mask structure on the second mold structure and having mask holes on the first region,
wherein the forming of the upper channel holes comprises anisotropically etching the second mold structure that is exposed by the mask holes.

14. The method of claim 13, wherein the mask structure comprises a hard mask layer, an etch stop layer, and a photoresist layer, which are sequentially stacked on the mold structure, and
a thickness of the hard mask layer is larger than a thickness of the etch stop layer.

15. The method of claim 12, wherein a top surface of the first sacrificial pillar and a top surface of the first dummy sacrificial pillar are located at a level lower than a top surface of the first mold structure.

16. The method of claim 12, wherein each of the first sacrificial pillar and the first dummy sacrificial pillar comprises a first metal material, and
each of the second sacrificial pillar and the second dummy sacrificial pillar comprises a second metal material having an etch selectivity with respect to the first metal material.

17. The method of claim 12, wherein the second recessed key region is located at a level lower than an uppermost top surface of the second mold structure, when measured from a top surface of the substrate.

18. The method of claim 12, wherein a width of each of the dummy holes is larger than a width of each of the lower channel holes.

19. The method of claim 12, further comprising, after the forming of the upper channel holes:
removing the first and second sacrificial pillars from the lower channel holes; and
forming vertical structures in the lower channel holes and the upper channel holes.

20. The method of claim 12, further comprising:
replacing the first sacrificial layers with first conductive patterns; and
replacing the second sacrificial layers with second conductive patterns.
